(19) United States
(12) Patent Application Publication
(10) Pub. No.: US 2013/0037077 A1
(43) Pub. Date: Feb. 14, 2013

(54) SOLAR MODULE HAVING MULTIPLE JUNCTION BOXES

(71) Applicant: Zhen Zhang, Changzhou City (CN)

(72) Inventor: Zhen Zhang, Changzhou City (CN)

(73) Assignee: CHANGZHOU TRINA SOLAR ENERGY CO., LTD., Changzhou City (CN)

(21) Appl. No.: 13/642,150

(22) PCT Filed: Nov. 3, 2010
(86) PCT No.: PCT/CN2010/078383

§ 371 Date: Oct. 19, 2012

(30) Foreign Application Priority Data
Apr. 20, 2010 (CN) 201010152166.7

(51) Int. Cl. H01L 31/042

(52) U.S. Cl. 136/244

(57) ABSTRACT

The present invention provides a solar module having multiple junction boxes, including solar panels, which are series-connected in series via tabbing ribbons and junction boxes. The junction boxes include a junction box with diodes which has by-pass function, and junction box without diodes which has power output function. The junction box with diodes and the junction box without diodes are connected to the solar panels respectively via bus ribbons. The junction box with diodes and the junction box without diodes are connected via external cables. The junction box without diodes is connected to a junction box cable. By increasing the amount of junction boxes and decreasing the length of connecting solder ribbon the present invention solves the problem of relatively low output power and relatively high loss when the solar module in prior art is used.

### FIELD OF THE INVENTION

The invention relates to the technical field of solar cells, and more particularly, to a solar module having multiple junction boxes.

### DESCRIPTION OF THE PRIOR ART

Nowadays, there are many applications of solar energy. A single solar cell generally has a relatively low voltage, so it is necessary to series-connect dozens of solar cells together with solder ribbons, and package them with protective materials and fittings to form a solar module. The general material of the solder ribbon connecting solar cells is tin-lead-silver coated copper. Considering the packaging process of the solar modules the solder ribbon cannot be made too wide or too thick so the solar module has a relatively high resistance and the power losses on solder ribbons are also relatively high. In addition, the solar module in prior art usually has one junction box which is attached on the back of the solar module. Multiple by-pass diodes are arranged in the junction box. When the module works normally the diodes are reversed and off but when section of the solar cells in the solar module are shaded, the by-pass diodes which are connected to the shaded cells in the parallel manner are on, thus the module is prevented from being destructed by the heat which is produced due to the hot spot effect. Generally, one by-pass diode can protect 12-24 cells. For a large module, it is necessary to arrange more diodes to protect different arrays of cells to protect them from hot spot destruction. When a diode is switched on to protect the shaded cells, the heat produced by its function will greatly increase the temperature of the whole junction box, thus increasing the temperature of the other diodes which are off. Because these diodes are reversed, the increase in current leakage caused by the increase in temperatures will decrease the power of the whole solar module.

### SUMMARY OF THE INVENTION

The invention aims to eliminate the defects in the prior art, provide a solar module having multiple junction boxes and solve the problem of a relatively low power output and a relatively high loss existing in the prior art's solar module. It will do this by increasing the amount of the junction boxes and decreasing the length of the connecting solder ribbons.

The technical solution of the invention is: a solar module having multiple junction boxes, including solar panels which are series-connected via tabbing ribbon and junction boxes. The junction boxes include a junction box having diodes which has by-pass function and a junction box without diodes which has power output function. The junction box with diodes and the junction box without diodes are connected to the solar panels respectively via bus ribbons. The junction box with diodes and the junction box without diodes are connected via external cables. The junction box without diodes is connected to the junction box cable.

Furthermore, the junction boxes without diodes are arranged on the same side of the solar module when the solar panels have an even number of arrays.

The junction boxes without diodes are arranged at the opposite sides of the solar module when the solar panels have an odd number of arrays.

The benefits of the invention are that by applying a connection pattern with multiple junction boxes the invention effectively decreases the power loss of the solar module, enhances its efficiency and enhances the reliability and security of the module as well. The invention decreases the costs of the module's materials for per unit power, the maintenance cost and reaches its ultimate aim to decrease the cost of solar power which facilitates the popularization and application of the renewable solar energy.

### BRIEF DESCRIPTION OF THE DRAWINGS

Following the invention will be further described with reference with the accompanying figures and embodiments.

FIG. 1 is a structural schematic diagram of the invention with an even number of solar cell arrays;

FIG. 2 is a structural schematic diagram of the invention with an odd number of solar cell arrays;

FIG. 3 is a structural schematic diagram of the invention for large solar module.

In the figures, 1 is a tabbing ribbon; 2 is a solar panel; 3 is a junction box having diodes; 4 is a junction box without diodes; 5 is a bus ribbon; 6 is a external cable; 7 is a junction box cable.

### DETAILED DESCRIPTION OF THE PREFERRED EMBODIMENTS

The invention is further described with reference to the accompanying figures. These figures are all schematic diagrams which only illustrate the basic structures of the invention, so they only show the structures relating to the invention.

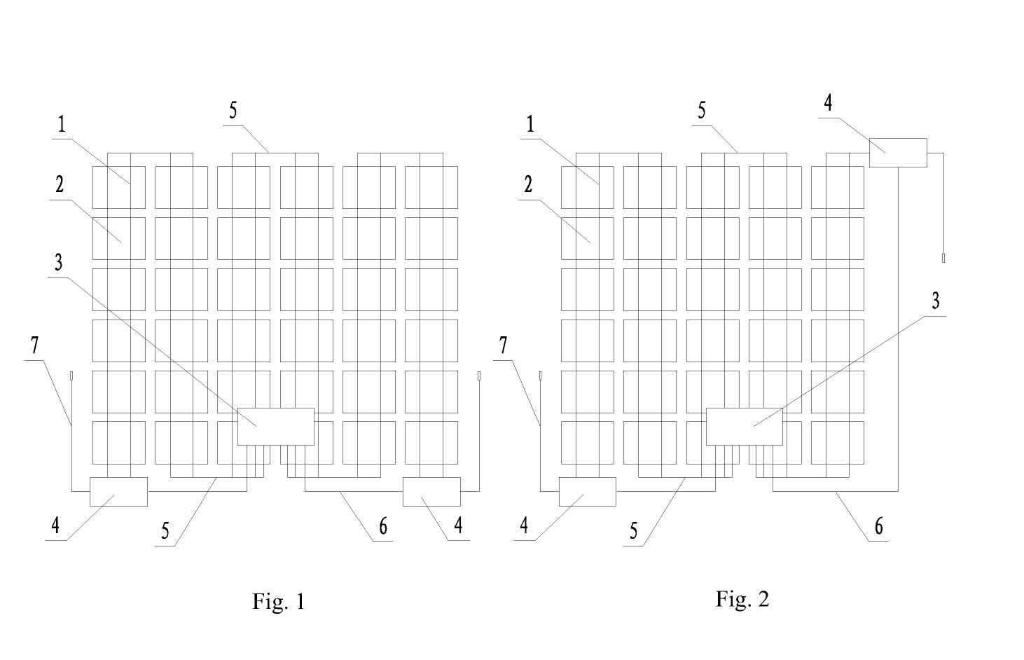

As shown in FIG. 1, it is the solar module having multiple junction boxes with an even number of solar cell arrays, which includes solar panels 2 and junction boxes, wherein the solar panels 2 are series-connected by a tabbing ribbon 1 to form a solar cell array. The adjacent solar cell arrays have two adjacent ends connected via the bus strip 5. The junction boxes include one junction box 3 with diodes and two junction boxes 4 without diodes, wherein the junction box 3 with diodes and junction boxes 4 without diodes are connected to the other two adjacent ends of the solar cell arrays via bus strip 5. The junction box 3 with diodes is connected to the junction boxes 4 without diodes via the external cable 6. The junction boxes 4 without diodes are connected to the junction box cable 7 to facilitate the output of the solar energy current. This structure uses two junction boxes 4 without diodes leading the cables out from the same side of the module, and the junction box 3 with diodes arranged in the middle of the module. With this design, the module's current output can decrease the power loss, and the decreased value is roughly 0.5-1 Wp, which approximately equals the power loss caused by the resistance of 0.8 m bus strip 5.

As shown in FIG. 2, it is the solar module having multiple junction boxes with an odd number of solar cell arrays. The difference between this and that shown in FIG. 1 is that the positions of the arranged junction boxes 4 without diodes are not same. Sometimes it is necessary to connect an odd number of cell arrays in the solar module to satisfy the dimensional requirement. If a single junction box is used to connect them, the positive and negative electrodes of the module cannot be led out from the same side, so it's necessary to have a longer bus strip 5. To solve this problem, two junction boxes 4 without diodes are led out from the two sides of the module. They are connected to the junction box 3 with diodes via the cable 6, which protects the cells from the hot spot by the diodes' by-pass function. A 1.5 m long module using this design with a power loss caused by a 1.6 m bus strip 5 can be decreased by 1-2 Wp.

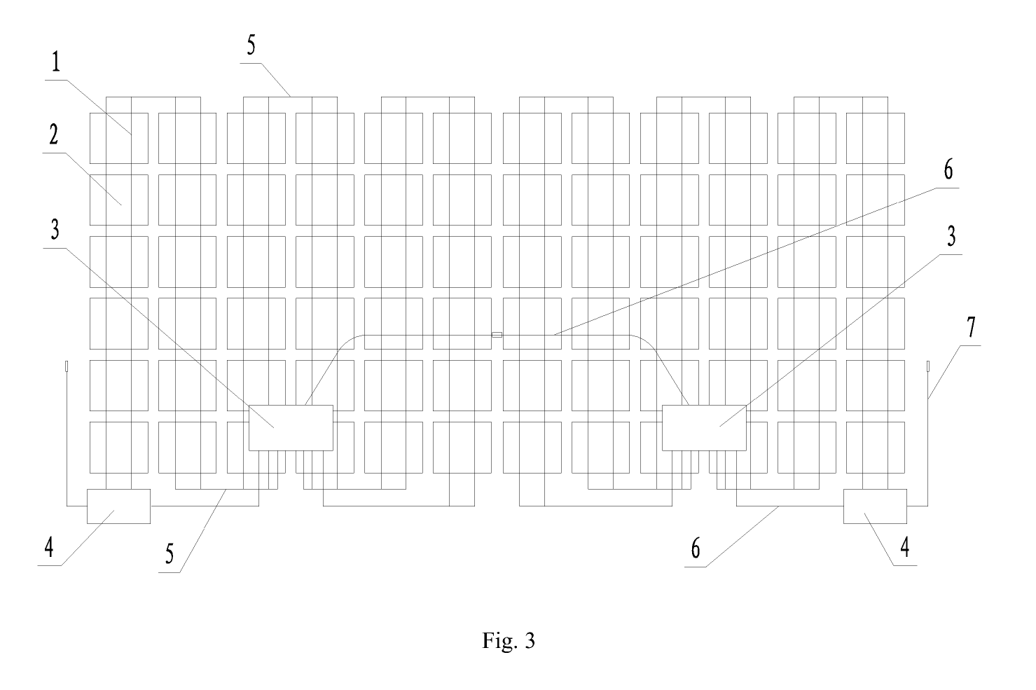

FIG. 3 is a structural schematic diagram of the invention for a large solar module. Similarly, the solar panels 2 and junction boxes are included, wherein the solar panels 2 are series-connected via tabbing strip 1 to form a solar cell array. The adjacent solar cell arrays have two adjacent ends connected via the bus strip 5. The junction boxes include two junction boxes with diodes 3 and two junction boxes 4 without diodes, wherein the junction boxes with diodes 3 and junction boxes 4 without diodes are connected to the other two adjacent ends of the solar cell arrays via the bus strip 5 respectively. The two junction boxes with diodes 3 are connected to the junction boxes 4 without diodes via the external cable 6. The two junction boxes with diodes 3 are connected to each other via the external cable 6 too. The junction boxes 4 without diodes are connected with the junction box cable 7 to facilitate the output of the solar energy current. For a large solar module (with over 72 cells) one junction box 3 with diodes needs to protect over 20 solar cells when single junction box 3 with diodes is used for connection (the present junction box 3 with diodes has no more than 4 diodes in it for heat dissipation). When shading occurs during the module's operation the reverse voltage applied on the shaded cells is very high and the high temperature caused by the hot spot is very likely to destruct the module. By using two junction boxes having diodes 3, the risk of the solar cells being destructed by the hot spot is greatly decreased and the reliability and security of the module are enhanced. At the same time, there are multiple junction boxes having diodes 3 being connected, so the temperatures of the diodes in the junction boxes having diodes 3 are relatively low and the leakage current of the diodes is small. This decreases the power loss of the module as well. So the large solar module which is assembled by using multiple junction boxes with diodes 3 and junction boxes 4 without diodes can have a decreased length of tabbing ribbon 1 used and a decreased power loss caused by the tabbing ribbon 1.

By increasing the amount of the junction boxes of the solar module the invention realizes a decrease in the loss of the output power of the module. On one hand, this structure can have the diodes dispersed to decrease the temperature in the junction boxes and decrease the loss of the power output of the module; on the other hand multiple junction boxes being connected via external cable 6 decreases the length of the inner connecting solder ribbons. Because the external cable 6 is outside of the module and can be connected directly whereas connecting solder ribbons cannot be connected directly due to the insulation requirement of the cells. The external cable 6 has a much bigger cross section area than the connecting solder ribbon and it greatly decreases the series resistance, thus further decreases the loss of the output power of the module and enhances the working efficiency of the module.

1. A solar module having multiple junction boxes, including solar panels (2) which are series-connected by a tabbing ribbon (1), and junction boxes, characterized in that the junction boxes include a junction box (3) with diodes, which has by-pass function, and a junction box (4) without diodes, which has power output function; the junction box (3) with diodes and the junction box (4) without diodes are connected to the solar panels (2) respectively via bus ribbons (5); the junction box (3) with diodes and the junction box (4) without diodes are connected via external cables (6); and the junction box (4) without diodes is connected to a junction box cable (7).

2. The solar module having multiple junction boxes according to claim 1, characterized in that the junction boxes (4) without diodes are arranged at the same side of the solar module when the solar panels (2) have an even number of arrays.

3. The solar module having multiple junction boxes according to claim 1, characterized in that the junction boxes (4) without diodes are arranged at the opposite sides of the solar module when the solar panels (2) have an odd number of arrays.
